(19) United States
(12) Patent Application Publication
(10) Pub. No.: US 2022/0109125 A1
(43) Pub. Date: Apr. 7, 2022

(54) DISPLAY PANEL AND DISPLAY DEVICE

(71) Applicant: Shenzhen China Star Optoelectronics Semiconductor Display Technology Co., Ltd., Shenzhen (CN)

(72) Inventor: Yan XUE, Shenzhen (CN)

(73) Assignee: Shenzhen China Star Optoelectronics Semiconductor Display Technology Co., Ltd., Shenzhen (CN)

(21) Appl. No.: 16/762,929

(22) PCT Filed: Apr. 21, 2020
(86) PCT No.: PCT/CN2020/085813

§ 371 Date: May 10, 2020

(30) Foreign Application Priority Data
Apr. 8, 2020 (CN) 202010268785.6

(51) Int. Cl. H01L 51/52; H01L 27/32

(52) U.S. Cl. CPC H01L 51/5237; H01L 27/3246

(57) ABSTRACT

A display panel and a display device are provided. A projected pattern of an active layer on a substrate is adjusted to make a projection area of a gate electrode layer on the substrate remain within a projection area of the active layer on the substrate, thereby eliminating side channels of the active layer existing in current display panels and further preventing a hump phenomenon caused by a separation of a main channel from side channels in an I-V curve, which is caused by inconsistent film-forming thicknesses of a gate insulating layer in the side channel and the main channel areas.

### FIELD OF INVENTION

The present disclosure relates to the field of display technologies, and more particularly, to a display panel and a display device.

### BACKGROUND OF INVENTION

Display devices can convert computer data into various characters, numbers, symbols or intuitive images for display, can input commands or data into computers by using an input tool such as a keyboard, and can add, modify, and change display contents at any time by means of hardware and software of the system. Display devices can be classified as plasma, liquid crystals, light emitting diodes, and cathode ray tubes, depending on the display devices used.

Organic light-emitting diode (OLED) display devices are also known as organic electroluminescent display devices or organic light-emitting semiconductors. The working principle of OLEDs is: when an electric power is applied to a moderate voltage, holes in a positive electrode and electrons in a cathode combine in a light-emitting layer and form excitons (electron-hole pairs) which are in an excited state by a certain probability under the effect of Coulomb forces. The excited state is not stable in an ordinary environment, and the excitons in the excited state will transfer an energy to the light-emitting material and make the light-emitting material excited from a ground state energy level to an excited state. An energy of the excited state generates photons by the process of radiation relaxation, thereby releasing light energy and producing light. Three primary colors of red, green, and blue (RGB) are produced, depending on different formulas and constitute basic color.

Since OLEDs have advantages of low voltage requirements, high power saving efficiency, fast response times, light weight, thinness, simple structures, low cost, wide viewing angles, high contrast, and low power consumption, they have become one of the most important display technologies as of today.

Technical problem: as shown in FIG. 1, an array substrate 100 in a current display panel comprises a substrate 101, a buffer layer 102, an active layer 103, a gate insulating layer 104, and a gate electrode layer 105.

As shown in FIG. 1, side channels 106 and a main channel 107 are defined in the array substrate 100. Wherein, edge ramps of the active layer 103 are defined as the side channels 106, and a center of the active layer 103 is defined as the main channel 107. The gate insulating layer 104 disposed on the active layer 103 has a step structure on edges (that is, the side channels 106) of the active layer 103, which easily causes the gate insulating layer 104 to form a thinner film on the edges of the active layer 103 and form a thicker film on the center (that is, the main channel 107) of the active layer 103 that makes covering thicknesses of the gate insulating layer 104 in the main channel 107 area and the side channel 106 areas being different. Therefore, the gate electrode layer 105 has varying control capabilities between the active layer 103 in the main channel 107 area and the active layer 103 in the side channel 106 areas, and when a TFT is subjected to an electrical stress continuously, the gate electrode layer 105 has different stresses for the active layer 103 in the main channel 107 area and the active layer 103 in the side channel 106 areas, so when a same voltage is provided to drive the TFT, separation of the main channel 107 from the side channels 106 occurs in an I-V curve and shows a hump phenomenon, thereby affecting a display's effectiveness and having lower reliability. Therefore, it is necessary to provide a new type of display panel to solve the above problems.

### SUMMARY OF INVENTION

An objective of the present disclosure is to provide a display panel and a display device to solve separation of a main channel from side channels occurring in an I-V curve, which shows a hump phenomenon, and thus affects display effect and has lower reliability.

To solve the above problems, an embodiment of the present disclosure provides a display panel. The display panel comprises: a substrate; an active layer disposed on the substrate; a gate insulating layer partially covering the active layer; and a gate electrode layer disposed on the gate insulating layer; wherein a projection area of the gate electrode layer on the substrate is defined within a projection area of the active layer on the substrate.

further, a graphic shape of projection of the active layer on the substrate coincides with a graphic shape of projection of the gate electrode layer on the substrate.

Further, the projection of the gate electrode layer on the substrate is a first serpentine line, and the projection of the active layer on the substrate is a second serpentine line.

Further, a length of the first serpentine line is less than or equal to a length of the second serpentine line.

Further, a width of the first serpentine line is less than or equal to a width of the second serpentine line.

Further, the display panel further comprises a buffer layer disposed between the substrate and the active layer.

Further, the display panel also comprises an interlayer insulating layer disposed on the gate electrode layer and extending to cover the substrate; a source and drain electrode layer disposed on the interlayer insulating layer and connected to the active layer through via holes; and a passivation layer disposed on the source and drain electrode layer and extending to cover the interlayer insulating layer.

Further, the display panel also comprises a first electrode disposed on the passivation layer and connected to the source and drain electrode layer through a through-hole; a pixel definition layer disposed on the passivation layer on both sides of the first electrode; a light-emitting layer disposed on the first electrode; and a second electrode disposed on the light-emitting layer.

Further, the display panel also comprises an encapsulation layer disposed on the second electrode.

To solve the above problems, an embodiment of the present disclosure further provides a display device which comprises the display panel of the present disclosure.

Beneficial effect: the present disclosure provides a display panel and a display device through adjusting a projected pattern of an active layer on a substrate to make a projection area of a gate electrode layer on the substrate within a projection area of the active layer on the substrate, thereby eliminating side channels of the active layer existing in current display panels and further preventing a hump phenomenon caused by separation of a main channel from the side channels in an I-V curve, which is caused by inconsistent film forming thicknesses of a gate insulating layer in side channel and main channel areas, thereby improving display effect and reliability of the display panel.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a schematic structural diagram of an array substrate of a display panel in current technology.

FIG. 2 is a schematic structural diagram of a display panel according to an embodiment of the present disclosure.

FIG. 3 is a schematic diagram of an overlapped projected pattern of an active layer and a gate electrode layer on a substrate according to an embodiment of the present disclosure.

FIG. 4 is a schematic diagram of a projected pattern of an active layer on a substrate according to an embodiment of the present disclosure.

FIG. 5 is a schematic diagram of a projected pattern of a gate electrode layer on a substrate according to an embodiment of the present disclosure.

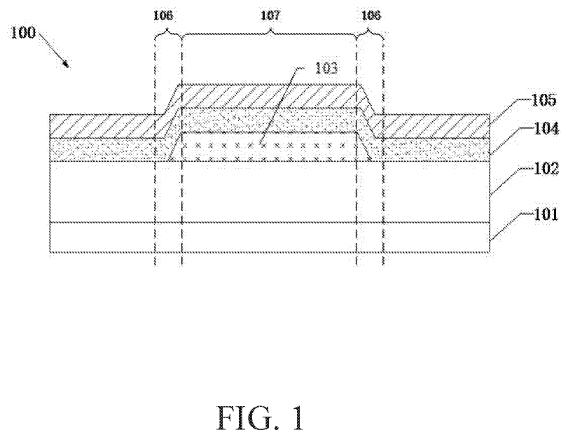

Elements in the drawings are designated by reference numerals listed below.
100. array substrate in current technology; 101. substrate; 102. buffer layer; 103. active layer; 104. gate insulating layer; 105. gate electrode layer; 106. side channel; 107. main channel; 200. display panel; 1. substrate; 2. buffer layer; 3. active layer; 4. gate insulating layer; 5. gate electrode layer; 6. interlayer insulating layer; 7. source and drain electrode layer; 8. passivation layer; 9. first electrode; 10. pixel definition layer; 11. light-emitting layer; 12. second electrode; 13. encapsulation layer; 31. second serpentine line; 51. first serpentine line.

### DETAILED DESCRIPTION OF PREFERRED EMBODIMENTS

The preferred embodiments of the present disclosure are described in detail below with reference to the accompanying drawings. The specific embodiments described with reference to the attached drawings are all exemplary and are intended to illustrate and interpret the present disclosure to make the skilled in the art easier to understand how to implement the present disclosure. The disclosure herein provides many different embodiments or examples for realizing different structures of the present disclosure. They are only examples and are not intended to limit the present disclosure.

In the description of the present disclosure, it should be understood that terms such as “upper”, “lower”, “front”, “rear”, “left”, “right”, “inside”, “outside”, “side”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure.

In the accompanying drawings, wherein the identical or similar reference numerals constantly denote the identical or similar elements or elements having the identical or similar functions. In the drawings, structurally identical components are denoted by the same reference numerals, and structural or functionally similar components are denoted by like reference numerals. Moreover, a size and a thickness of each component shown in the drawings are arbitrarily shown for ease of understanding and description, and the present disclosure does not limit the size and thickness of each component.

When a component is described as “on” another component, the component can be placed directly on the other component; an intermediate component can also exist, the component is placed on the intermediate component, and the intermediate component is placed on another component. When a component is described as “installed to” or “connected to” another component, it can be understood as directly “installed to” or “connected to”, or a component is “mounted to” or “connected to” another component through an intermediate component.

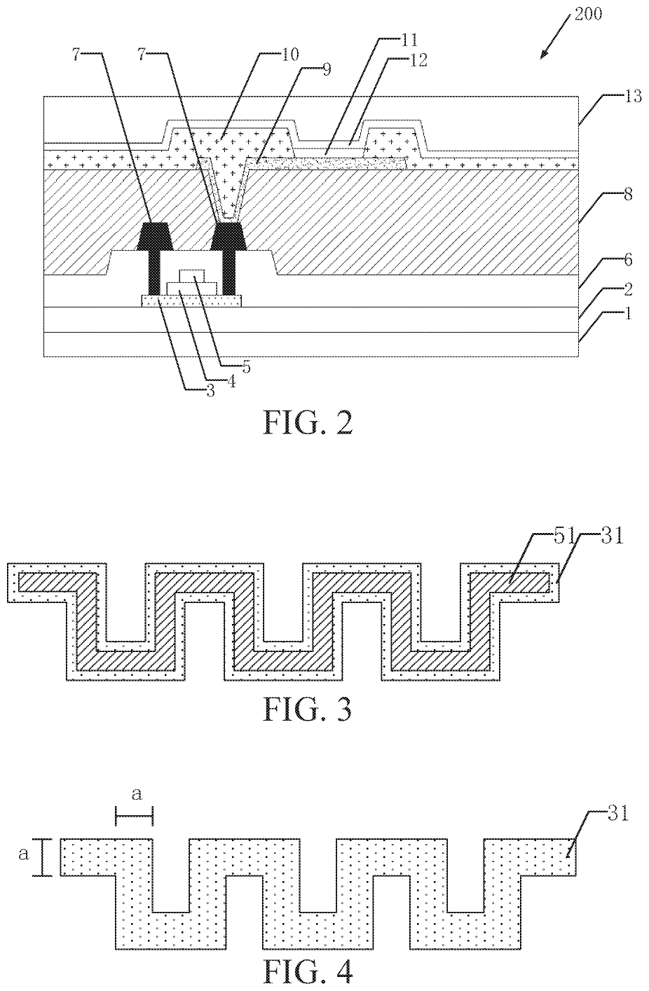

As shown in FIG. 2, an embodiment of the present disclosure provides a display device which comprises a display panel 200. The display panel 200 includes a substrate 1, a buffer layer 2, an active layer 3, a gate insulating layer 4, a gate electrode layer 5, an interlayer insulating layer 6, a source and drain electrode layer 7, a passivation layer 8, a first electrode 9, a pixel definition layer 10, a light-emitting layer 11, a second electrode 12, and an encapsulation layer 13.

The substrate 1 may use a flexible substrate. The substrate 1 has water and oxygen blocking effect and may also have a better impact resistance, which can effectively protect the display panel 100. A material for the substrate 1 comprises one or more of glass, silicon dioxide, polyethylene, polypropylene, polystyrene, polylactic acid, polyethylene terephthalate, polyimide, or polyurethane.

The buffer layer 2 is disposed on the substrate 1 and mainly serves as buffering and protection. A material for the buffer layer 2 comprises one or more of silicon dioxide (SiO₂) or silicon nitride (SiNₓ).

The active layer 3 is disposed on the buffer layer 2. A material for the active layer 3 is oxide semiconductor, and indium gallium zinc oxide (IGZO) is preferred in the embodiment.

The gate insulating layer 4 partially covers the active layer 3 and is mainly used to prevent contact between the gate electrode layer 5 and the active layer 3 from generating a short circuit. A material for the gate insulating layer 4 may be one or more of SiO₂ or SiNₓ.

The gate electrode layer 5 is disposed on the gate insulating layer 4, and a material thereof is a metal, such as copper (Cu) or molybdenum (Mo).

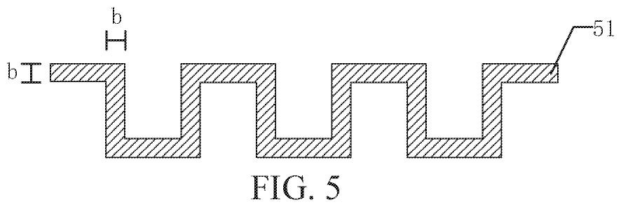

As shown in FIGS. 2 to 5, a projection area of the gate electrode layer 5 on the substrate 1 is defined within a projection area of the active layer 3 on the substrate 1. Thus, through making projection of the gate electrode layer 5 on the substrate 1 totally within projection of the active layer 3 on the substrate 1, the present disclosure can eliminate side channels of the active layer 3 existing in current display panels and further prevent a hump phenomenon caused by separation of a main channel from the side channels in an I-V curve, which is caused by inconsistent film forming thicknesses of the gate insulating layer 4 in side channel and main channel areas, thereby improving effectiveness and reliability of the display panel 100.

As shown in FIGS. 2 to 5, a graphic shape of projection of the active layer 3 on the substrate 1 coincides with a graphic shape of projection of the gate electrode layer 5 on the substrate 1. That is, the two have similar patterns.

As shown in FIGS. 2 to 5, the projection of the gate electrode layer 5 on the substrate 1 is a first serpentine line 51, and the projection of the active layer 3 on the substrate 1 is a second serpentine line 31.

A length of the first serpentine line 51 is less than or equal to a length of the second serpentine line 31. Wherein, the length of the first serpentine line 51 is an expanded length of the first serpentine line 51, and the length of the second serpentine line 31 is an expanded length of the second serpentine line 31. Wherein, a width of the second serpentine line 31 is a, a width of the first serpentine line 51 is b, and the width b of the first serpentine line 51 is less than or equal to the width a of the second serpentine line 31. Thus, it can ensure that the projection area of the gate electrode layer 5 on the substrate 1 is defined within the projection area of the active layer 3 on the substrate 1. Therefore, the present disclosure can eliminate side channels of the active layer 3 existing in current display panels and further prevent a hump phenomenon caused by separation of a main channel from the side channels in an I-V curve, which is caused by inconsistent film-forming thicknesses of the gate insulating layer 4 in side channel and main channel areas, thereby improving effectiveness and reliability of the display panel 100.

The interlayer insulating layer 6 is disposed on the gate electrode layer 4 and extends to cover the buffer layer 2. A material for the interlayer insulating layer 6 may be one or more of SiO₂ or SiNₓ.

The source and drain electrode layer 7 is disposed on the interlayer insulating layer 6 and is connected to the active layer 3 through via holes. A material for the source and drain electrode layer 7 is a metal, such as copper (Cu) or molybdenum (Mo). Therefore, the source and drain electrode layer 7 can obtain electrical signals from the active layer 3, and provide the electrical signals for light emission of the display panel 200.

The passivation layer 8 is disposed on the source and drain electrode layer 7 and extends to cover the interlayer insulating layer 6. In one aspect, the passivation layer 8 may be used to protect underlying film layers, and in another aspect, the passivation layer 8 may also have a planarization effect, providing a flat surface for manufacturing upper layers.

The first electrode 9 is disposed on the passivation layer 8 and is connected to the source and drain electrode layer 7 through a through-hole. Therefore, the first electrode 9 can obtain the electrical signals from the active layer 3 through the source and drain electrode layer 7, and provide the electrical signals for light emission of the display panel 200. Since nano indium tin metal oxide (ITO) has good conductivity and light transmittance, a material for the first electrode 9 in the embodiment is preferably ITO.

The pixel definition layer 10 is disposed on the passivation layer 9 on both sides of the first electrode 9, and the pixel definition layer 10 is mainly used to prevent adjacent pixels from generating optical crosstalk.

The light-emitting layer 11 is disposed on the first electrode 9, and a material for the light-emitting layer 11 comprises organic electroluminescent materials.

The second electrode 12 is disposed on the light-emitting layer 11. Since nano indium tin metal oxide (ITO) has good conductivity and light transmittance, a material for the second electrode 12 in the embodiment is preferably ITO.

The encapsulation layer 13 is disposed on the second electrode 12. The encapsulation layer 13 is mainly used to block water and oxygen, thereby preventing internal devices of the display panel 200 from being eroded and aged by external water and oxygen, reducing the service life of the display panel 200. Specifically, the encapsulation layer 13 may include a first inorganic encapsulation layer, an organic encapsulation layer, and a second inorganic encapsulation layer. Wherein, the first inorganic encapsulation layer and the second inorganic encapsulation layer are mainly used to block water and oxygen, and the organic encapsulation layer mainly acts as a buffer and releases stresses absorbed by the encapsulation layer 13, increasing bendability of the display panel 200.

The display panel and the display device provided by the present disclosure are described in detail above. The specific examples are applied in the description to explain the principle and implementation of the disclosure. The description of the above embodiments is only for helping to understand the technical solution of the present disclosure and its core ideas, and it is understood that many changes and modifications to the described embodiment can be carried out without departing from the scope and the spirit of the disclosure that is intended to be limited only by the appended claims.

1. A display panel, comprising:
a substrate;
an active layer disposed on the substrate;
a gate insulating layer partially covering the active layer; and
a gate electrode layer disposed on the gate insulating layer;
wherein a projection area of the gate electrode layer on the substrate is defined within a projection area of the active layer on the substrate.

2. The display panel according to claim 1, wherein a graphic shape of a projection of the active layer on the substrate coincides with a graphic shape of a projection of the gate electrode layer on the substrate.

3. The display panel according to claim 1, wherein the projection of the gate electrode layer on the substrate is a first serpentine line, and the projection of the active layer on the substrate is a second serpentine line.

4. The display panel according to claim 3, wherein a length of the first serpentine line is less than or equal to a length of the second serpentine line.

5. The display panel according to claim 3, wherein a width of the first serpentine line is less than or equal to a width of the second serpentine line.

6. The display panel according to claim 1, comprising:
a buffer layer disposed between the substrate and the active layer.

7. The display panel according to claim 1, comprising:
an interlayer insulating layer disposed on the gate electrode layer and extending to cover the substrate;
a source and drain electrode layer disposed on the interlayer insulating layer and connected to the active layer through via holes; and
a passivation layer disposed on the source and drain electrode layer and extending to cover the interlayer insulating layer.

8. The display panel according to claim 7, comprising:
a first electrode disposed on the passivation layer and connected to the source and drain electrode layer through a through-hole;
a pixel definition layer disposed on the passivation layer on both sides of the first electrode;
a light-emitting layer disposed on the first electrode; and
a second electrode disposed on the light-emitting layer.

9. The display panel according to claim 8, comprising:
an encapsulation layer disposed on the second electrode.

10. A display device, comprising a display panel, wherein the display panel comprises:
a substrate;
an active layer disposed on the substrate;
a gate insulating layer partially covering the active layer; and
a gate electrode layer disposed on the gate insulating layer;
wherein a projection area of the gate electrode layer on the substrate is defined within a projection area of the active layer on the substrate.

11. The display device according to claim 10, wherein a graphic shape of a projection of the active layer on the substrate coincides with a graphic shape of a projection of the gate electrode layer on the substrate.

12. The display device according to claim 10, wherein the projection of the gate electrode layer on the substrate is a first serpentine line, and the projection of the active layer on the substrate is a second serpentine line.

13. The display device according to claim 12, wherein a length of the first serpentine line is less than or equal to a length of the second serpentine line.

14. The display device according to claim 12, wherein a width of the first serpentine line is less than or equal to a width of the second serpentine line.

15. The display device according to claim 10, wherein the display panel further comprises:
a buffer layer disposed between the substrate and the active layer.

16. The display device according to claim 10, wherein the display panel further comprises:
an interlayer insulating layer disposed on the gate electrode layer and extending to cover the substrate;
a source and drain electrode layer disposed on the interlayer insulating layer and connected to the active layer through via holes; and
a passivation layer disposed on the source and drain electrode layer and extending to cover the interlayer insulating layer.

17. The display device according to claim 16, wherein the display panel further comprises:
a first electrode disposed on the passivation layer and connected to the source and drain electrode layer through a through-hole;
a pixel definition layer disposed on the passivation layer on both sides of the first electrode;
a light-emitting layer disposed on the first electrode; and
a second electrode disposed on the light-emitting layer.

18. The display device according to claim 17, wherein the display panel further comprises:
an encapsulation layer disposed on the second electrode.
